(19) United States
(12) Patent Application Publication
(10) Pub. No.: US 2007/0220410 A1
(43) Pub. Date: Sep. 20, 2007

(54) Apparatus and method for iterative decoding in a communication system

(75) Inventors: Seul-Ki Bae, Suwon-si (KR); June Moon, Seoul (KR)

Correspondence Address: THE FARRELL LAW FIRM, P.C., 333 EARLE OVINGTON BOULEVARD, SUITE 701, UNIONDALE, NY, 11553, US

(73) Assignee: SAMSUNG ELECTRONICS CO., LTD., Suwon-si (KR)

(21) Appl. No.: 11/704,460

(22) Filed: Feb. 9, 2007

(30) Foreign Application Priority Data
Feb. 9, 2006 (KR) 12611-2006

(51) Int. Cl. G06F 11/00; H03M 13/00

(52) U.S. Cl. 714/800

(57) ABSTRACT

Disclosed are an apparatus and a method for iterative decoding of a plurality of Frame Error Check (FEC) blocks included in a frame in a wireless communication system. The method includes decoding a first FEC block by considering a first decoding iteration count; determining whether there is another FEC block to be decoded; newly setting a second decoding iteration count for a second FEC block when there is the second FEC block, in such a manner that a number of times of the iterative decoding is actually used for decoding the first FEC block is subtracted from the first decoding iteration count, and the obtained difference value is added to the second decoding iteration count, which has been set for the second FEC block; and decoding the second FEC block by considering the newly set second decoding iteration count.

### PRIORITY

This application claims the benefit under 35 U.S.C. §119(a) to an application filed in the Korean Industrial Property Office on Feb. 9, 2006 and assigned Serial No. 2006-012611, the contents of which are incorporated herein by reference.

### BACKGROUND OF THE INVENTION

1. Field of the Invention

The present invention relates generally to a communication system, and in particular, to an apparatus and a method for efficiently performing iterative decoding.

2. Description of the Related Art

In general, the larger a decoding iteration count set for a decoder, the higher the decoding capability of the decoder. Therefore, most communication systems employing iterative decoding usually set a maximum iteration count to a value of 50 or more in order to achieve high decoding capability. However, in a communication system using a frequency bandwidth of 1 G (gigahertz), a decoding iteration count cannot be set to a high value. The performance of iterative decoding deteriorates when, as described above, a decoding iteration count is not set to a sufficiently high value.

FIG. 1 is a view for explaining an example of a system operation in a communication system in which a decoding iteration count is set to 6.

Referring to FIG. 1, a conventional decoder performs iterative decoding for an input signal, and if parity check conditions are satisfied, that is, if decoding succeeds, terminates the decoding process even before a preset decoding iteration count (that is, 6) is reached. In other words, in FIG. 1, a decoding iteration count is preset to 6 for every decoding block, but if decoding succeeds at the second iterative decoding in any decoding block, the remaining four times is not necessary. Thus, the decoder does not perform the remaining four-times iterative decoding in order to minimize power consumption.

However, the above-mentioned case is premised on the assumption that channel conditions are good and thus decoding succeeds only by performing iterative decoding a few number of times. For example, when a communication system requiring high-speed signal processing is under bad channel conditions, there may occur a case where iterative decoding must be performed a large number of times. However, since such a communication system must process signals at high speed, a large decoding iteration count leads to a delay in signal processing. Therefore, there is a need for a way to perform iterative decoding adaptively to a high-speed communication system in which a limited decoding iteration count must be set.

### SUMMARY OF THE INVENTION

Accordingly, the present invention has been made to solve the above-mentioned problems occurring in the conventional art, and an object of the present invention is to provide an apparatus and a method for variably adjusting a decoding iteration count in a wireless communication system.

A further object of the present invention is to provide an apparatus and a method for improving decoding capability in a wireless communication system requiring a high-speed communication environment.

In order to accomplish these objects, in accordance with an aspect of the present invention, there is provided a method for iterative decoding of a plurality of Frame Error Check (FEC) blocks included in a frame in a wireless communication system. The method includes decoding a first FEC block by considering a decoding iteration count set for the first FEC block, that is, a first decoding iteration count, the decoding iteration count denoting a maximum allowable number of times of iterative decoding and being set for each of the plurality of FEC blocks; determining whether there is another FEC block to be decoded; newly setting a second decoding iteration count for a second FEC block when the second FEC block is different from the first FEC block, in such a manner that a number of times of the iterative decoding is actually used for decoding the first FEC block is subtracted from the first decoding iteration count to thereby obtain a difference value, and the obtained difference value is added to the second decoding iteration count which has been set for the second FEC block; and decoding the second FEC block by considering the newly set second decoding iteration count.

In accordance with another aspect of the present invention, there is provided an apparatus for performing iterative decoding for a plurality of Frame Error Check (FEC) blocks included in a frame of a wireless communication system. The apparatus includes a controller for controlling decoding of a first FEC block by considering a decoding iteration count set for each of the FEC blocks, determining whether there is another FEC block to be decoded, resetting a second decoding iteration count for a second FEC block when the second FEC block is different from the first FEC block, in such a manner that a number of times of the iterative decoding is actually used for decoding the first FEC block is subtracted from the decoding iteration count set for the first FEC block to thereby obtain a difference value and the obtained difference value is added to the second decoding iteration count which has been set for the second FEC block, and controlling decoding of the second FEC block by considering the reset second decoding iteration count; and a decoder for decoding the first and second FEC blocks under a control of the controller by considering the decoding iteration count and the reset decoding iteration count.

### BRIEF DESCRIPTION OF THE DRAWINGS

The above and other objects, features and advantages of the present invention will be more apparent from the following detailed description taken in conjunction with the accompanying drawings, in which:

FIG. 1 is a diagram for explaining an example of a system operation in a communication system in which a decoding iteration count is set to 6;

FIG. 2 is a diagram for explaining an example of variably performing iterative decoding in a communication system in which a decoding iteration count per Frame Error Check (FEC) block is set to 6, according to the present invention;

FIG. 3 is a flowchart illustrating a procedure in which a receiving end performs decoding by variably adjusting a decoding iteration count, according to the present invention; and

FIG. 4 is a block diagram schematically illustrating a transmitting-/receiving-end device to which the present invention may be applied.

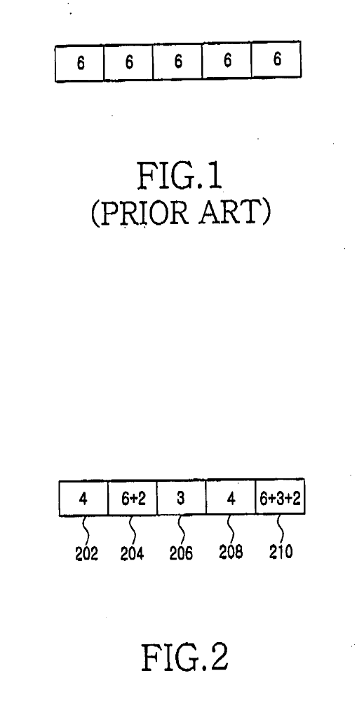

### DETAILED DESCRIPTION OF THE PREFERRED EMBODIMENT

Hereinafter, preferred embodiments of the present invention will be described with reference to the accompanying drawings. In the following description, the same elements will be designated by the same reference numerals although they are shown in different drawings. Further, various specific definitions found in the following description, such as specific values of packet identifications, contents of displayed information, etc., are provided only to help general understanding of the present invention, and it is apparent to those skilled in the art that the present invention can be implemented without such definitions. Further, in the following description of the present invention, a detailed description of known functions and configurations incorporated herein will be omitted when it may make the subject matter of the present invention rather unclear.

The present invention provides an apparatus and a method, which can improve iterative decoding capability in a communication system having a limited decoding iteration count. A receiving end including a decoder according to the present invention performs iterative decoding for a first Frame Error Check (FEC) block. Here, a plurality of FEC blocks are included in a frame, and the decoder performs error check in units of FEC blocks. The receiving end may include at least one such decoders. If decoding of an FEC block succeeds by performing iterative decoding only N times when a decoding iteration count is set to M (M<N), the receiving end according to the present invention uses the remaining decoding iteration count, that is, a decoding iteration count of M-N, for decoding a next FEC block.

The present invention may be applied to all communication systems employing iterative decoding. A typical communication system employing iterative decoding is a communication system using a Low Density Parity Check (LDPC) code.

FIG. 2 is a diagram for explaining an example of variably performing iterative decoding in a communication system in which a decoding iteration count per FEC block is set to 6, according to the present invention.

Referring to FIG. 2, in a first FEC block 202, decoding is completed by performing iterative decoding only four times from among 6 times corresponding to an allowable decoding iteration count. Thus, two-times iterative decoding remains, and it is, therefore, possible to perform iterative decoding 8 times for a second FEC block by adding the remaining two times to the decoding iteration count of 6. That is, in the second FEC block 204, decoding is not completed even when iterative decoding is performed 6 times corresponding to the preset decoding iteration count, and iterative decoding must be performed a total of 8 times, including two-times iterative decoding transferred from the first FEC block 202, before decoding is completed.

In a third FEC block 206, decoding is completed by performing iterative decoding only 3 times from among 6 times corresponding to the preset decoding iteration count, and the remaining three times can be used when a fourth FEC block 208 is decoded. In the fourth FEC block 208, decoding is completed by performing iterative decoding only 4 times from among a total of 9 times, and the remaining 5 times can be used when a fifth FEC block 210 is decoded. In the fifth FEC block 210, iterative decoding can be performed a total of 11 times corresponding to the preset decoding iteration count of 6 plus the excess 5 times transferred from the fourth FEC block 208, and decoding is completed by performing iterative decoding 11 times. That is, in the fifth FEC block 210, “3” of “6+3+2” shown in FIG. 2 denotes the remaining number of times of iterative decoding, transferred from the third FEC block 206, and “2” denotes the remaining number of times of iterative decoding, transferred from the fourth FEC block 208.

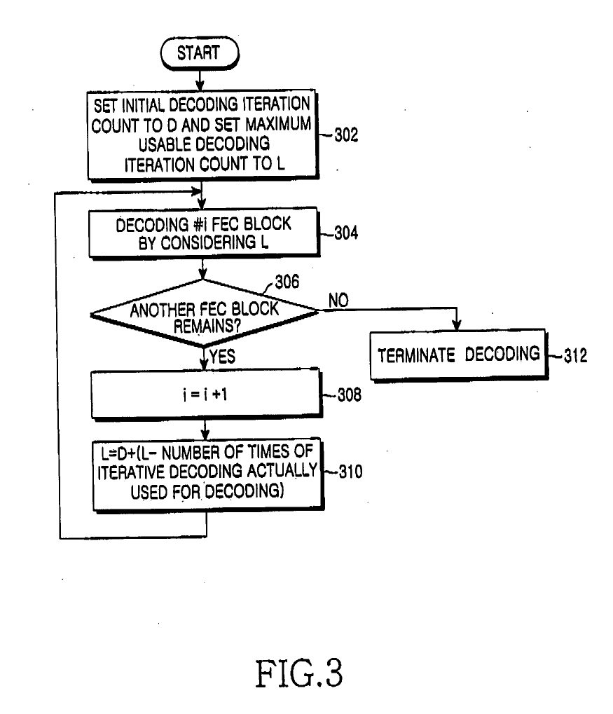

FIG. 3 is a flowchart illustrating a procedure in which a receiving end performs decoding by variably adjusting a decoding iteration count, according to the present invention.

Referring to FIG. 3, in step 302, the receiving end first sets an initial decoding iteration count per FEC block to a constant value, D, sets a maximum usable decoding iteration count to a constant value, L, and then proceeds to step 304. Here, the initial decoding iteration count refers to the number of times of iterative decoding, initially set for each FEC block, for example, 6 times as shown in FIG. 2, and the maximum usable decoding iteration count refers to the number of times of iterative decoding, which changes when iterative decoding is performed for the corresponding FEC block, for example, (6+2) times for the second FEC block in FIG. 2.

In step 304, the receiving end performs decoding for an FEC block corresponding to #i by considering L, and then proceeds to step 306. Here, the FEC block corresponding to #i is in a state where the initial decoding iteration count is set to D. Thus, for the FEC block, iterative decoding can be performed from one time to D times, and when decoding is completed before D is reached, the remaining number of times of iterative decoding is used in decoding a next FEC block. That is, it can be noted that the value of L is the same as the value of D when the first FEC block (#i) is decoded.

In step 306, the receiving end determines if there is an FEC block to be decoded. According to a result of the determination, the receiving end proceeds to step 308 if an FEC block to be decoded remains, and proceeds to step 310 and terminates decoding, if there is no FEC block to be decoded.

In step 308, the receiving end increase the value of i by one, and proceeds to step 310. In step 310, the receiving end must reset the value of L in order to decode a next FEC block, that is, an FEC block corresponding to #(i+1). L is reset according to Equation (1) as expressed below:
L=D+(L−number of times of iterative decoding used for decoding previous FEC block) (1)
After the receiving end resets the value of L according to Equation (1), it proceeds to step 304, and performs decoding for the FEC block corresponding to #(i+1).

The initial decoding iteration count is set to 6 for all the FEC blocks, and the maximum usable decoding iteration count for each of the FEC blocks is set to L. For the first FEC block, that is, an FEC block corresponding to #1, the initial decoding iteration count of 6 is set as L.

If the number of times of iterative decoding used for decoding the FEC block 202 corresponding to #i is 4, the maximum usable decoding iteration count for an FEC block 204 corresponding to #(i+1) becomes 8 by calculating 6+(6−4) according to Equation (1). If the number of times of iterative decoding used for decoding the FEC block corresponding to #(i+1), the maximum usable decoding iteration count for an FEC block 206 corresponding to #(i+2) becomes 6 by calculating 6+(8−8) according to Equation (1). The FEC block 206 corresponding to #(i+2) can be decoded by performing iterative decoding only 3 times, and the remaining 3 times can be used for a next FEC 208 block corresponding to #(i+3). The FEC block 208 corresponding to #(i+3) can be decoded by performing iterative decoding only 4 times, and the remaining 5 times can be used for a next FEC 210 block corresponding to #(i+4).

Although all of the FEC blocks in FIGS. 2 and 3 are set to have the same initial decoding iteration count, it may be possible to set the initial decoding iteration counts for the respective FEC blocks to the same value or different values. That is, the initial decoding iteration count for an FEC block located in the head of the frame is set to a value larger than that for an FEC block located at the rear end of the frame. Setting the larger initial decoding iteration count for the FEC block located in the head of the frame is intended to balance an average decoding iteration count for each FEC block.

According to a first embodiment of the present invention, the FEC block located at the rear end of the frame can ensure a sufficient decoding iteration count, but the decoding iteration count for the FEC block located in the head of the frame may be relatively small. If bad channel conditions causes an error in the FEC block located in the head of the frame, decoding capability may deteriorate because of the small decoding iteration count. Therefore, according to another embodiment of the present invention, a large decoding iteration count is set for the FEC block located in the head of the frame, and the remaining number of times of iterative decoding is used for decoding the FEC block located in the rear end of the frame. However, the total sum of the decoding iteration counts set for the respective FEC blocks must not exceed the overall decoding iteration count set for in the communication system.

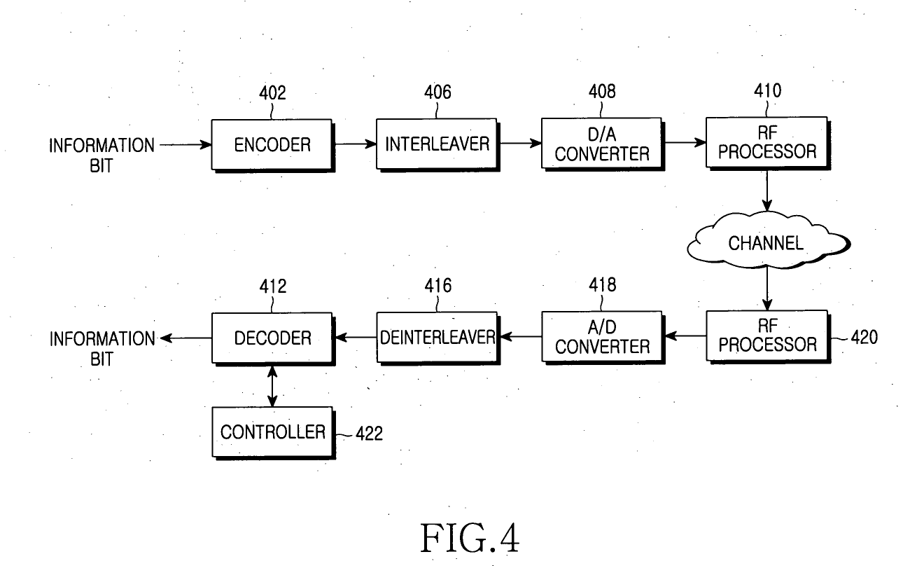

FIG. 4 is a block diagram schematically illustrating a transmitting-/receiving-end device to which the present invention may be applied.

Referring to FIG. 4, the transmitting end includes an encoder 402, an interleaver 406, a Digital-to-Analog converter (D/A converter) 408, and a Radio Frequency (RF) processor 410.

The receiving end includes an RF processor 420, an Analog-to-Digital converter (A/D converter) 418, a deinterleaver 416, a decoder 412, and a controller 422.

If an information bit is input into the encoder 402, the encoder 402 encodes the input information bit in a predetermined coding scheme, and then outputs encoded packets to the interleaver 406. Here, the encoder 402 may use a turbo coding scheme or a convolution coding scheme with a predetermined coding rate. The interleaver 406 interleaves the encoded input packets, and then outputs an interleaved digital signal to the D/A converter 408. The D/A converter 468 converts the input digital signal into an analog signal, and then outputs the converted analog signal to the RF processor 410. The RF processor 410 RF-processes the input analog signal in such a manner as to be actually transmitted on air, and then transmits the processed signal on air through a transmit antenna (Tx antenna).

Since the receiving end operates in a reverse manner to that of the transmitting end, a detailed description thereof will be omitted. However, it should be noted that the receiving end includes the controller 422 and the decoder 412 according to the present invention. That is, the decoder 412 employs demodulation and decoding schemes corresponding to modulation and encoding schemes used in the transmitting end, and can perform iterative decoding under the control of the controller 422. The controller 422 controls the decoder 412 in such a manner as to perform iterative decoding for a corresponding FEC block and uses the remaining number of times of iterative decoding for decoding a next FEC block. Further, the controller 422 sets the initial decoding iteration count and the maximum usable decoding iteration count for each FEC block, and controls the decoder 412 in consideration of the initial decoding iteration count and the maximum usable decoding iteration count set for each FEC block.

When the present invention is applied to an LDPC transmitting/receiving end, an encoder and a decoder of the transmitting/receiving end uses an LDPC code. Further, when the present invention is applied to a communication system employing a Multiple Input Multiple Output (MIMO) scheme, a MIMO mapper and a MIMO demapper may be added to the transmitting/receiving end.

As described above herein, according to the present invention, a decoding iteration count can be variably adjusted in a communication system having a small decoding iteration count for improving the decoding capability of the communication system.

While the present invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for iterative decoding of a plurality of Frame Error Check (FEC) blocks included in a frame in a wireless communication system, the method comprising the steps of:
decoding a first FEC block by considering a decoding iteration count set for the first FEC block, that is, a first decoding iteration count, the decoding iteration count denoting a maximum allowable number of times of iterative decoding and being set for each of the plurality of FEC blocks;
determining whether there is another FEC block to be decoded;
newly setting a second decoding iteration count for a second FEC block when the second FEC block is different from the first FEC block, in such a manner that a number of times of the iterative decoding is actually used for decoding the first FEC block is subtracted from the first decoding iteration count to thereby obtain a difference value, and the obtained difference value is added to the second decoding iteration count which has been set for the second FEC block; and
decoding the second FEC block by considering the newly set second decoding iteration count.

2. The method as claimed in claim 1, wherein the first and second decoding iteration counts are set in such a manner as to have different values.

3. The method as claimed in claim 1, wherein the first and second decoding iteration counts are set in such a manner as to have the same value.

4. The method as claimed in claim 1, wherein the first and second decoding iteration counts are set in such a manner as to have the same value or different values.

5. The method as claimed in claim 1, wherein the decoding iteration counts per FEC block does not exceed the first or second decoding iteration count set for each of the FEC blocks and the newly set second decoding iteration count.

6. An apparatus for performing iterative decoding for a plurality of Frame Error Check (FEC) blocks included in a frame in a wireless communication system, the apparatus comprising:
a controller for controlling decoding of a first FEC block by considering a decoding iteration count set for each of the FEC blocks, determining whether there is another FEC block to be decoded, resetting a second decoding iteration count for a second FEC block when the second FEC block is different from the first FEC block, in such a manner that a number of times of the iterative decoding is actually used for decoding the first FEC block is subtracted from the decoding iteration count set for the first FEC block to thereby obtain a difference value and the obtained difference value is added to the second decoding iteration count which has been set for the second FEC block, and controlling decoding of the second FEC block by considering the reset second decoding iteration count; and
a decoder for decoding the first and second FEC blocks under a control of the controller by considering the decoding iteration count and the reset second decoding iteration count.

7. The apparatus as claimed in claim 6, wherein the controller sets the first and second decoding iteration counts in such a manner as to have different values.

8. The apparatus as claimed in claim 6, wherein the controller sets the first and second decoding iteration counts in such a manner as to have the same value.

9. The apparatus as claimed in claim 6, wherein the controller sets the first and second decoding iteration counts in such a manner as to have the same value or different values.
